(19) United States
(12) Patent Application Publication
(10) Pub. No.: US 2016/0273104 A1
(43) Pub. Date: Sep. 22, 2016

(54) POLYOLEFINS HAVING LONG LASTING HYDROPHILIC INTERFACES

(71) Applicant: BAR ILAN UNIVERSITY, RAMAT GAN (IL)

(72) Inventors: Chaim SUKENIK, NOF AYALON (IL); YACOV CARMIEL, GIVAT SHMUEL (IL)

(21) Appl. No.: 15/171,451

(22) Filed: Jun. 2, 2016

Related U.S. Application Data
(63) Continuation-in-part of application No. PCT/IL2014/051044, filed on Dec. 2, 2014.
(60) Provisional application No. 61/910,993, filed on Dec. 3, 2013.

(51) Int. Cl. C23C 16/455; C23C 16/50; C23C 16/48

(52) U.S. Cl. CPC C23C 16/45525; C23C 16/48; C23C 16/50

(57) ABSTRACT

This invention provides hydrophilic polyolefins coated by a metal oxide layer, preparation and uses thereof as paintable and adherable surfaces.

### CROSS REFERENCE TO RELATED APPLICATIONS

This application is a Continuation-in-Part application of International Application Number PCT/IL2014/051044 filed Dec. 2, 2014, which claims priority of U.S. Ser. No. 61/910,993, filed Dec. 3, 2013 which is hereby incorporated by reference in its entirety.

### FIELD OF THE INVENTION

This invention provides hydrophilic polyolefins coated by metal oxide layer, preparation and uses thereof as paintable and adherable surfaces.

### BACKGROUND OF THE INVENTION

The surface of polyolefins is normally very hydrophobic and this prevents the application of paints, surface treatments etc. Current approaches use various oxidative treatments to make the polyolefin surface hydrophilic but this hydrophilicity is short-lived (hours) under ambient conditions.

Available methods to make polyolefins more hydrophilic include: coating with a surfactant (or surface active agent or wetting agent); coating with a polymer(s), the polymer(s) having different and better surface active properties than the polyolefin; surface activation (e.g., by plasma treatment); surface roughing to increase surface area (e.g., foaming the surface); and blending the polyolefins with another polymer(s), where the blend has different and better surface active properties than the polyolefin.

In the foregoing methods, the hydrophilicity of the polyolefin may degrade over time and/or the bulk properties of the polyolefin are compromised. Accordingly, there is a need for a robust hydrophilic polyolefin.

A known approach for preserving surface hydrophilicity by a secondary treatment is by applying a hydrophilic polymer to the surface of the activated polyolefin. This approach creates a much less versatile and much less robust interface than the invention disclosed herein.

The technology described herein is the key to being able to modify the surface of polyolefins in a systematic, robust fashion. It enables the painting and gluing of polyolefin surfaces and their incorporation into multi-layer implements of any size or shape.

### SUMMARY OF THE INVENTION

In one embodiment, this invention is directed to a hydrophilic polyolefin article comprising a polyolefin substrate, which comprises at least one polyolefin, coated with a thin film layer of a metal oxide.

In one embodiment this invention is directed to a method for producing a hydrophilic polyolefin article comprising a polyolefin substrate, said method comprising:
(i) oxidizing one or more surfaces of the polyolefin substrate;
(ii) coating said one or more surfaces of the polyolefin substrate with a thin film layer of metal oxide.

In one embodiment, this invention is directed to a method of producing a hydrophilic polyethylene coated with a uniform layer of metal oxide having a thickness of about 50 nm, said method comprising:
(i) providing a polyethylene substrate;
(ii) oxidizing one or more surfaces of the polyethylene substrate by plasma;
(iii) immersing the one or more oxidized surfaces of the polyethylene substrate into an aqueous solution containing metal oxide forming reagent for a sufficient period of time at 20-40° C., to thereby coat said one or more oxidized surfaces with a uniform 50 nm thick layer of metal oxide; and
(iv) drying the metal oxide-coated polyethylene substrate obtained in step (iii) at a temperature in the range of 25 to 70° C. and at a relative humidity in the range of 20-70%.

In one embodiment, this invention is directed to a method for restoration of the hydrophilicity of a hydrophilic polyolefin article as described above, said method comprising exposing the metal oxide layer of the hydrophilic polyolefin article to ultra violet (UV) light for a sufficient period of time.

### BRIEF DESCRIPTION OF THE DRAWINGS

FIG. 1: depicts an Electron Microscope image of a polyethylene substrate coated by titania according to this invention. In this case, 50 nm of titania was deposited onto the polyethylene substrate so as to establish the desired long term hydrophilicity.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

It has been found in accordance with the present invention that activation of the hydrophobic surface of polyolefins, e.g., polyethylene, to make it hydrophilic, and preservation of the hydrophilicity of the surface by application of a thin layer of a metal oxide e.g., titania, enable the painting, gluing, and surface treatment of the hydrophilic polyolefin surface, as well as their incorporation into multi-layer implements of any size or shape. The metal oxide layer stays hydrophilic and remains adherent to the polyolefin surface even under stress.

Accordingly, the present invention relates to hydrophilic polyolefins. In one embodiment, this invention is directed to a hydrophilic polyolefin article comprising a polyolefin substrate, which comprises at least one polyolefin, coated with a thin film layer of a metal oxide. More particularly, the present invention relates to hydrophilic shaped polyolefin structures having surfaces modified by the presence of a thin layer of metal oxide coating, which renders such surfaces hydrophilic.

As used herein, the term “shaped polyolefin structure” is used broadly to include any solid form of a polyolefin, in contrast to a polyolefin in a gaseous or liquid phase, or in solution. Thus, the polyolefin can be a molded article, an extruded shape, fibers, woven or nonwoven fabrics, films, or the like.

As used herein, the term “hydrophilic polyolefin article/substrate” refers to any solid article based on polyolefin comprising boxes, containers, powder or granules or chips, a molded article, an extruded shape, fibers, woven or nonwoven fabrics, films, or the like.

In one embodiment, the polyolefin article of this invention is coated with a thin layer of metal oxide.

Polyolefins are a class or group of thermoplastic polymers derived from simple olefins. For the purposes of the present disclosure, the term “polyolefin” refers to any polymer a major constituent of which, i.e., at least 50 percent by weight, is a polyolefin. Thus, the term includes homopolymers, copolymers, and polymer blends. With respect to bi- or polycomponent structures, the major constituent requirement applies only to the component having the surface or surfaces to be treated by the method of the present invention. By way of illustration only, examples of bicomponent structures include sheath-core fibers in which the sheath is a polyolefin as defined herein, and a core of a polystyrene or polyurethane foam encased in a rigid polyolefin shell.

In one embodiment, polyolefins include polyethylene, polypropylene, polybutylene, polymethyl pentene, and copolymers thereof. More specific examples of polyolefins include: polyethylene, polystyrene, poly(vinyl chloride), poly(vinyl acetate), poly(vinylidene chloride), poly(acrylic acid), poly(methacrylic acid), poly(methyl methacrylate), poly(ethyl acrylate), polyacrylamide, polyacrylonitrile, polypropylene, poly(1-butene), poly(2-butene), poly(1-pentene), poly(2-pentene), poly(3-methyl-1-pentene), poly(4-methyl-1-pentene), 1,2-poly-1,3-butadiene, 1,4-poly-1,3-butadiene, polyisoprene, polychloroprene, and the like.

In one embodiment, the hydrophilic polyolefin article/substrate of this invention and methods of use thereof comprise at least one polyolefin. In another embodiment, the polyolefin is polyethylene. In another embodiment, the polyolefin is polpropylene. In another embodiment, the polyolefin is polybutylene. In another embodiment, the polyolefin is polymethylpentene. In another embodiment, the polyolefin is polyethylene, polypropylene, polybutylene, polymethylpentene, a copolymer thereof, or any combination thereof.

In one embodiment, the hydrophilic polyolefin article/substrate of this invention and methods of use thereof comprise at least one polyolefin. “At least one polyolefin” refers to between one to three polyolefins. In another embodiment, “At least one polyolefin” refers to one type of polyolefin.

Copolymers refer to random or block copolymers of two or more polyolefins (or two or more different polyolefin monomeric precursors) or of one or more polyolefins and one or more nonpolyolefin polymers. Similarly, polymer blends utilize two or more polyolefins or one or more polyolefins and one or more nonpolyolefin polymers.

In one embodiment, the polyolefin is selected from a group comprising homopolymers, copolymers, random polymers, and/or block (co)polymers. In one embodiment, the polyolefin is selected from a group comprising homopolymers, copolymers, random polymers, and/or block (co)polymers of ethene or propene. In another embodiment, the polyolefin includes copolymers with higher alkenes, in particular butene, hexene, and/or octene.

In certain embodiments, the substrate/article of this invention comprising polyolefin. In another embodiment, the polyolefin is polyethylene such as a high density polyethylene (HDPE), low density polyethylene (LDPE), very low density polyethylene (VLDPE), linear low density polyethylene (LLDPE), medium density polyethylene (MDPE), ultra-high molecular polyethylene (UHMPE), crosslinked polyethylene (XLPE), high-pressure polyethylene (HPPE) or any combination thereof. In other certain embodiments, the polyolefin is polypropylene such as an isotactic polypropylene, syndiotactic polypropylene, metallocene catalyzed polypropylene impact-modified polypropylene, biaxially oriented polypropylene (BOPP) or any combination thereof. In further certain embodiments, the polyolefin is a copolymer selected from a random or blocks copolymer based on ethylene and propylene. In another embodiment, the random or block copolymer based on ethylene and propylene ispoly[ethylene-co-propylene](EPM).

In another embodiment, the polyolefin is graft copolymer, such as polymer blends, i.e., mixtures of polymers, which contain, among other things, the above-referenced polymers, for example, polymer blends based on polyethylene and polypropylene.

In another embodiment, the polyolefin is copolymers of ethene and/or propene with higher olefins and/or diolefins.

In one embodiment, this invention provides a hydrophilic polyolefin article comprising a polyolefin substrate coated with a thin layer of metal oxide, and methods of use thereof. In certain embodiments, the metal oxide is selected from titania (TiO₂), alumina (Al₂O₃), zirconia (ZrO₂), zinc oxide (ZnO), tin oxide (SnO₂) or combinations thereof. In one embodiment, the metal oxide is titania (TiO₂). In one embodiment, the metal oxide is alumina (Al₂O₃). In one embodiment, the metal oxide is zirconia (ZrO₂). In one embodiment, the metal oxide is zinc oxide (ZnO). In one embodiment, the metal oxide is tin oxide (SnO₂).

Metal oxide layers of hydrophilic polyolefin article according to this invention, are about a few nanometers to a few microns in thickness. In one embodiment, the thin film layer of the metal oxide is uniform and has a thickness of about 5 nm to about 30 μm, about 10 nm to about 20 μm, about 20 nm to about 10 μm, about 30 nm to about 5 μm, about 40 nm to about 1 μm, about 45 nm to about 600 nm, about 50 nm to about 200 nm, about 10 nm to about 100 nm, about 15 nm to about 50 nm, about 40 nm to about 60 nm, or about 50 nm to about 100 nm. In one embodiment, the metal oxide film layer has a thickness of about 50 nm. In one embodiment, the metal oxide film layer has a thickness of about 15 nm. In one embodiment, the metal oxide film layer has a thickness of about 20 nm. In another embodiment, the hydrophilic polyolefin article of the invention is comprised of a polyethylene substrate coated with a uniform 50 nm thick layer of metal oxide. In another embodiment, the hydrophilic polyolefin article of the invention is comprised of a polyethylene substrate coated with a uniform 15 nm thick layer of metal oxide. In another embodiment, the hydrophilic polyolefin article of the invention is comprised of a polyethylene substrate coated with a uniform 20 nm thick layer of metal oxide. In another embodiment the metal oxide is titania. In another embodiment the metal oxide is alumina. In another embodiment the metal oxide is tin oxide.

The term “about” as used herein means within an acceptable error range for a particular value as determined by one of ordinary skill in the art, which will depend in part on how the value is measured or determined, i.e., the limitations of the measurement system. For example, “about” can mean a range of up to 20%, preferably up to 10%, more preferably up to 5%, still more preferably up to 1% of a given value. Where particular values are described in the description and claims, unless otherwise stated, the term “about” means that an acceptable error range for the particular value should be assumed.

The term “room temperature” refers in this invention to experimental condition that does not require heating. In another embodiment, room temperature refers to a temperature between 10 to 40° C. deg. In another embodiment, room temperature refers to a temperature between 20 to 30° C. deg. In another embodiment, room temperature refers to a temperature between 15 to 30° C. deg. In another embodiment, room temperature refers to a temperature between 20 to 40° C. deg.

The hydrophilic polyolefin article of the invention has any size or shape without limitation, and may be in any form, including but not limited to: granules, chips, pellets, films, sheets, fibers, tubes, pipes, woven or nonwoven fabrics, a molded article, an extruded shape, or powders.

In one embodiment, the present invention relates to a method of producing a hydrophilic polyolefin article comprising a polyolefin substrate, said method comprises:
(i) oxidizing one or more surfaces of the polyolefin substrate;
(ii) coating said one or more surfaces of the polyolefin substrate with a thin film layer of metal oxide.

In another embodiment, the method further comprises a step of drying the metal oxide coated polyolefin substrate obtained in step (ii) under conditions that minimize cracking of said metal oxide layer. In another embodiment, the method does not involve a specific drying step. In another embodiment, the method further comprises a step of quick drying. In another embodiment, the quick drying is carried out under vacuum, heat or a combination thereof.

In one embodiment, the present invention relates to a method of producing a hydrophilic polyolefin article comprising a polyolefin substrate, said method comprises:
(i) oxidizing one or more surfaces of the polyolefin substrate;
(ii) coating said one or more surfaces of the polyolefin substrate with a thin film layer of metal oxide; and
(iii) drying the metal oxide coated polyolefin substrate obtained in step (ii) under conditions that minimize cracking of said metal oxide layer.

In one embodiment, this invention provides a method for the preparation of durable, lasting, polyolefin surfaces to which adhesives, dyes, inks, and coatings adhere, said method comprises:
(i) oxidizing one or more surfaces of a polyolefin substrate;
(ii) coating said one or more surfaces of the polyolefin substrate with a thin film layer of metal oxide.

In another embodiment, the method further comprises a step of drying the metal oxide coated polyolefin substrate obtained in step (ii) under conditions that minimize cracking of said metal oxide layer. In another embodiment, the method does not involve a specific drying step. In another embodiment, the method further comprises a step of quick drying. In another embodiment, the quick drying is carried out under vacuum, heat or combination thereof.

In one embodiment, this invention provides a method for the preparation of durable, lasting, polyolefin surfaces to which adhesives, dyes, inks, and coatings adhere, said method comprises:
(i) oxidizing one or more surfaces of a polyolefin substrate;
(ii) coating said one or more surfaces of the polyolefin substrate with a thin film layer of metal oxide; and
(iii) drying the metal oxide coated polyolefin substrate obtained in step (ii) under conditions that minimize cracking of said metal oxide layer.

In one embodiment, this invention provides a method of imparting hydrophilic properties to a surface of a shaped polyolefin, said method comprises:
(i) oxidizing one or more surfaces of a polyolefin structure;
(ii) coating said one or more surfaces of the polyolefin structure with a thin film layer of metal oxide.

In another embodiment, the method further comprises a step of drying the metal oxide coated polyolefin structure obtained in step (ii) under conditions that minimize cracking of said metal oxide layer. In another embodiment, the method does not involve a specific drying step. In another embodiment, the method further comprises a step of quick drying. In another embodiment, the quick drying is carried out under vacuum, heat or combination thereof.

In one embodiment, this invention provides a method of imparting hydrophilic properties to a surface of a shaped polyolefin structure said method comprises:
(i) oxidizing one or more surfaces of a polyolefin structure;
(ii) coating said one or more surfaces of the polyolefin structure with a thin film layer of metal oxide; and
(iii) drying the metal oxide coated polyolefin structure obtained in step (ii) under conditions that minimize cracking of said metal oxide layer.

According to the methods of the present invention, the oxidation step (i) of one or more surfaces of the polyolefin substrate is performed using any initial activation method known in the art. In another embodiment, the oxidation step (i) is performed by plasma, flame, ozone, ultra violet ozone cleaning systems (UVOCS), or etching with an oxidative solution. In a certain embodiment, the oxidation of said one or more surfaces is performed by plasma. In another embodiment the plasma intensity is 30 W; or in another embodiment, 45 W; or in another embodiment, 60 W; or in another embodiment, 75 W; or in another embodiment, 90 W; or in another embodiment, 100 W; or in another embodiment, 250 W; or in another embodiment, 500 W; or in another embodiment, 500 W; or in another embodiment, 600 W; or in another embodiment, 800 W; or in another embodiment, 1000 W; or in another embodiment, 1250 W; or in another embodiment, 2000 W; or in another embodiment, 2500 W; or in another embodiment, 5000 W. In another embodiment, the oxidation by plasma of the polyolefin surface is carried out for 5 min; or in another embodiment, for 10 min; or in another embodiment, for 15 min; or in another embodiment, for 20 min; or in another embodiment, for 30 min; or in another embodiment, for 45 min; or in another embodiment, for 1 hr.; or in another embodiment, for 3 hrs. In another embodiment, the polyolefin is polyethylene. In a preferred embodiment, the polyolefin substrate used according to the methods of the present invention is polyethylene, whose one or more surfaces is oxidized by plasma for approximately 15 minutes at maximum intensity with air flow of 100-200 standard cubic centimeters per minute (sccm).

According to the methods of the present invention, the coating step (ii) is carried out by liquid phase deposition (LPD), atomic layer deposition (ALD) or vapor phase techniques.

Atomic layer deposition (ALD) of metal oxides on polyolefin articles according to this invention, involves 4 steps that are repeated in a cycle: 1) introducing the metal containing precursor (e.g. a titanium compound) and allowing it enough time to react with all available surface sites (e.g. 0.5 seconds); 2) evacuating the chamber to remove excess metal containing reagent (e.g. applying vacuum along with an argon purge); 3) introducing an oxygen source (e.g. water, oxygen) into the chamber and allowing it enough time to react with the new surface sites created by the treatment with the first reagent (e.g. 20 seconds); 4) evacuating the chamber to remove excess oxygen source reagent (e.g. vacuum along with an argon purge); then starting back at step one. The cycles may be repeated as a way of growing progressively thicker films, which in one embodiment can involve 10 cycles; or in another embodiment 50 cycles; or in another embodiment 100 cycles; or in another embodiment 200 cycles; or in another embodiment 500 cycles; or in another embodiment 1000 cycles; or in another embodiment 2000 cycles;

In one embodiment, the reagent used for coating in step (ii) is selected from: (NH₄)TiF₆/H₃BO₃ (for TiO₂ LPD), H₂SnF_{d}/H₃BO₃ (for SnO₂ LPD), Al(CH₃)₃/H₂O (for Al₂O₃ ALD), Al(CH₃)₃/O₂ (for Al₂O₃ ALD), Ti(NMe₂)₄/H₂O (for TiO₂ ALD), Ti(NMe₂)₄/O₂ (for TiO₂ ALD), and Zn(CH₂CH₃)₂/H₂O (for ZnO ALD), Zn(CH₂CH₃)₂/O₂ (for ZnO ALD), Sn(NMe₂)₄H₂O (for SnO₂ ALD) Sn(NMe₂)₄/O₂ (for SnO₂ ALD), Zr(NMe₂)₄/H₂O (for ZrO₂ ALD), and Zr(NMe₂)₄/O₂ (for ZrO₂ ALD). In another embodiment, the coating step is carried out by liquid phase deposition (LPD). In another embodiment, the reagent used for coating in step (ii) is (NH₄)TiF₆/H₃BO₃. In another embodiment, the reagent used for coating in step (ii) is H₂SnF₆/H₃BO₃. In another embodiment, the reagent used for coating in step (ii) is generated in situ. In another embodiment, H₂SnF₆ is synthesized in situ from SnF₂, HF and H₂O₂. In another embodiment, the coating step is carried out by atomic layer deposition (ALD). In another embodiment, the reagent used for coating in step (ii) is Ti(NMe₂)₄/O₂. In another embodiment, the reagent used for coating in step (ii) is Al(CH₃)₃/O₂. In certain embodiments, the coating step (ii) is carried out by liquid phase deposition, wherein said one or more oxidized surfaces of the polyolefin substrate obtained in step (i) are immersed into an aqueous solution containing (NH₄)TiF₆ and H₃BO₃ reagent for a sufficient period of time, which is in one embodiment, for 1 hr.; or in another embodiment, for 2 hrs.; or in another embodiment, for 3 hrs.; or in another embodiment, for about 4-8 hours; or in another embodiment, for about 5-7 hours; or in another embodiment, for 6 hrs.; or in another embodiment, for 4 hrs. In certain embodiments, the coating step (ii) is carried out by atomic layer deposition, wherein said one or more oxidized surfaces of the polyolefin substrate obtained in step (i) are introduced together with a metal oxide precursor, into a closed chamber where they react in a self-limiting fashion for a sufficient period of time, following by introduction of an oxygen source and allowing it to react with the new surface sites created by the treatment with the metal oxide forming reagent for a sufficient period of time. This ALD coating step can be repeated as many times as needed in order to progressively grow thicker films, which in one embodiment is 1000 times; or in another embodiment, 500 times; or in another embodiment, 200 times; or in another embodiment, 100 times; or in another embodiment, 50 times; or in another embodiment, 10 times.

In certain embodiments, the coating step (ii) is carried out immediately after step (i). In another embodiment, the coating step is carried out with some delay after step (i). In another embodiment, the coating step is carried out between about 1 and 5 minutes after step (i); or in another embodiment, between about 1 and 10 minutes after step (i); or in another embodiment, between about 1 and 15 minutes after step (i); or in another embodiment, between about 15 and 60 minutes after step (i); or in another embodiment, about 5 minutes after step (i); or in another embodiment, about 10 minutes after step (i); or in another embodiment, about 15 minutes after step (i).

In certain embodiments, said one or more oxidized surfaces of the polyolefin substrate obtained in step (i) of the method of the present invention are coated with a uniform layer of said metal oxide having a thickness of about 5 nm to about 30 μm, about 10 nm to about 20 μm, about 20 nm to about 10 μm, about 30 nm to about 5 μm, about 40 nm to about 1 μm, about 15 nm to about 600 nm, about 50 nm to about 200 nm, about 10 nm to about 100 nm, about 15 nm to about 70 nm, about 40 nm to about 60 nm, or about 50 nm to about 100 nm. In another embodiment, said one or more oxidized surfaces of the polyolefin substrate obtained in step (i) are coated with 50 nm layer of metal oxide. In another embodiment, said one or more oxidized surfaces of the polyolefin substrate obtained in step (i) are coated with 20 nm layer of metal oxide. In another embodiment, said one or more oxidized surfaces of the polyolefin substrate obtained in step (i) are coated with 15 nm layer of metal oxide.

In one embodiment, the one or more coated surfaces of the polyolefin obtained in step (ii) of the method of the present invention are optionally washed with a solvent prior to the drying step (iii). In another embodiment, the solvent is water, ethanol, methanol, isopropanol (IPA), n-propanol, n-butanol, isobutanol, dioxane, chloroform, diethyl ether, dichloromethane, tetrafydrofuran (THF), ethyl acetate, acetone, dimethylformamide (DMF), acetonitrile (MeCN), propylene carbonate, or any combination thereof. In another embodiment, the solvent is water. In another embodiment, the solvent is methanol.

In another embodiment, the one or more coated surfaces of the polyolefin obtained in step (ii) of the method of the present invention is optionally washed with water followed by washing with alcohol prior to the drying step (iii).

In another embodiment, in order to remove trapped water from said one or more coated surfaces of the polyolefin, additional washing with C₁-C₄ alcohol, such as methanol, ethanol, propanol, isopropanol, butanol, or isobutanol, preferably methanol or ethanol, most preferably methanol, is used.

In some embodiments, the methods according to this invention may further comprise a drying step. Using variable temperature and/or variable humidity during the drying step minimizes the cracking of the metal oxide layer coating on said one or more surfaces of said polyolefin substrate. However, even when a cracked film is obtained (in the absence of controlled conditions for drying for example), it is still highly adherent and still works well for most applications. Accordingly, in one embodiment, the methods according to this invention do not require a drying step.

In certain embodiments, the methods according to this invention, further comprise a drying step. In another embodiment, the drying step is carried out in controlled conditions.

Drying in “controlled conditions” typically refers to setting the temperature and humidity to a specific value, following by slowly reducing the relative humidity, while leaving the temperature at the same value or reducing the temperature in a controlled fashion. In one embodiment, the temperature is set at 70° C., or in another embodiment at 80° C.; or in another embodiment at 90° C.; or in another embodiment at 100° C.; or in another embodiment at 40° C.; or in another embodiment at 60° C. In one embodiment, the relative humidity is varied from 70% to 20%; or in another embodiment, from 100% to 40%; or in another embodiment, from 65% to 20%; or in another embodiment, from 60% to 35%. In another embodiment, the temperature is set at 70° C. and the relative humidity is varied from 70% to 20%.

Drying time can be varied and the rate of change of the humidity can be varied. This is all a function of the thickness of the oxide deposited and of the specific underlying olefin substrate. In one embodiment, in order to obtain crack-free oxide coatings, drying under controlled conditions can take as long as about three days; or in another embodiment, about 2 days; or in another embodiment, about 1 day; or in another embodiment, about 18 hours; or in another embodiment, about 12 hours; or in another embodiment, about 6 hours; or in another embodiment, about 3 hours; or in another embodiment, about 1 hour.

In another embodiment, the drying step is a quick drying that does not require controlled conditions. In one embodiment, the drying step is carried out under heat or vacuum, or combinations thereof. In another embodiment, the heating is carried out at a specific temperature range. In one embodiment, the temperature is in a range of 25° C. to 70° C. In another embodiment, the temperature is in a range of 15° C. to 100° C. In another embodiment, the temperature is in a range of 25° C. to 120° C. In another embodiment, the temperature is room temperature. In another embodiment, the temperature is in a range of 25° C. to 50° C. In another embodiment, the temperature is in a range of 40° C. to 70° C. In another embodiment the temperature is about 120° C.; or about 100° C.; or about 70° C.; or about 50° C.; or about 40° C.; or about 25° C. In one embodiment, the relative humidity is in a range of 20-70%. In another embodiment, the relative humidity is in a range of 40-100%. In another embodiment, the relative humidity is in a range of 20-65%. In another embodiment, the relative humidity is in a range of 35-60%. In another embodiment, the optional drying step in the method of the present invention is carried out at a temperature in the range of 25° C. to 70° C. and at a relative humidity in the range of 20-70%.

In one embodiment, this invention provides a method of producing a hydrophilic polyethylene coated with a uniform layer of metal oxide having a thickness of about 50 nm, said method comprises:
(i) providing a polyethylene substrate;
(ii) oxidizing one or more surfaces of the polyethylene substrate by plasma;
(iii) immersing the one or more oxidized surfaces of the polyethylene substrate into an aqueous solution containing metal oxide forming reagent for a sufficient period of time at 20-40° C., to thereby coat said one or more oxidized surfaces with a uniform 50 nm thick layer of metal oxide.

In another embodiment, the method further comprises a step of drying the titania-coated polyethylene substrate obtained in step (iii) at a temperature in the range of 25 to 70° C. and at a relative humidity in the range of 20-70%. In another embodiment, the drying is performed at controlled conditions. In another embodiment, the method does not involve a specific drying step. In another embodiment, the method further comprises a step of quick drying. In another embodiment, the quick drying is carried out under vacuum, heat or combination thereof. In another embodiment, the metal oxide is titania. In another embodiment, the metal oxide is tin oxide. In another embodiment, the metal oxide forming reagent is (NH₄)₂TiF₆/H₃BO₃. In another embodiment, the metal oxide forming reagent is H₂SnF₆/H₃BO₃. In another embodiment, the metal oxide forming reagent is SnF₂/HF/H₂O₂/H₃BO₃.

In one embodiment, this invention provides a method of producing a hydrophilic polyethylene coated with a uniform layer of metal oxide having a thickness of about 50 nm, said method comprises:
(i) providing a polyethylene substrate;
(ii) oxidizing one or more surfaces of the polyethylene substrate by plasma;
(iii) immersing the one or more oxidized surfaces of the polyethylene substrate into an aqueous solution containing metal oxide forming reagent for a sufficient period of time at 20-40° C., to thereby coat said one or more oxidized surfaces with a uniform 50 nm thick layer of metal oxide; and
(iv) drying the metal oxide-coated polyethylene substrate obtained in step (iii) at a temperature in the range of 25 to 70° C. and at a relative humidity in the range of 20-70%.

In another embodiment, the metal oxide is titania. In another embodiment, the metal oxide is tin oxide. In another embodiment, the metal oxide forming reagent is (NH₄)₂TiF₆/H₃BO₃. In another embodiment, the metal oxide forming reagent is H₂SnF₆/H₃BO₃. In another embodiment, the metal oxide forming reagent is SnF₂/HF/H₂O₂/H₃BO₃.

In one embodiment, the methods of this invention comprises an immersing step of one or more oxidized surfaces of the polyolefin substrate obtained in an aqueous solution containing metal oxide forming reagent for a sufficient period of time at room temperature. In another embodiment, the immersing step is conducted at a temperature of between 20-40° C. In another embodiment, the immersing step is conducted at a temperature of between 15-30° C. In another embodiment, the immersing step is conducted at a temperature of between 20-30° C.

In one embodiment, this invention provides a method of producing a hydrophilic polyolefin coated by atomic layer deposition with a uniform layer of metal oxide, said method comprises:
(i) providing a polyolefin substrate;
(ii) oxidizing one or more surfaces of the polyethylene substrate;
(iii) introducing said one or more oxidized surfaces of the polyolefin substrate and a metal oxide forming reagent into a closed chamber and allowing them to react for a sufficient period of time;
(iv) optionally evacuating said chamber to remove excess of metal oxide forming reagent;
(v) introducing an oxygen source into said chamber and allowing it to react for a sufficient period of time;
(vi) optionally evacuating the chamber to remove excess of said oxygen source;
(vii) repeating steps (iii)-(vi) as many times as needed; and
(viii) optionally drying the coated polyolefin substrate obtained in step (vi) or (vii) at a temperature in the range of 25 to 70° C. and at a relative humidity in the range of 20-70%.

In one embodiment, step (iii) and/or (v) may take few milliseconds; or in another embodiment, few seconds; or in another embodiment, few minutes. In another embodiment, the time required for accomplishing step (iii) and/or (v) is about 10 to 100 milliseconds; or about 50 milliseconds to about 5 seconds; or about 1 second to about 1 minute; or about 1 to 10 minutes; or about 0.5 second. In another embodiment, the metal oxide forming reagent is selected from: Al(CH₃)₃, Ti(NMe₂)₄. Sn(NMe₂)₄, Zr(NMe₂)₄ and Zn(CH₂CH₃)₂. In another embodiment the oxygen source is O₂. In another embodiment the oxygen source is H₂O. In another embodiment, the oxygen source is plasma. In another embodiment, the oxygen source is ozone. In another embodiment, the oxygen source is any oxygen source known to the skilled in the art. In another embodiment, the polyolefin substrate is polyethylene.

In another embodiment, this invention provides a method of restoring the hydrophilicity of a hydrophilic polyolefin article of the invention, said method comprises exposing the hydrophilic polyolefin surface, which comprises metal oxide coating layer, to ultra violet (UV) light for a sufficient period of time. In another embodiment, the hydrophilic polyolefin surface is exposed to UV light for up to 1 hour. In another embodiment, the hydrophilic polyolefin surface is exposed to UV light for 5-60 minutes. In another embodiment, the hydrophilic polyolefin surface is exposed to UV light for 8-20 minutes. In another embodiment, the hydrophilic polyolefin surface is exposed to UV light for 10 minutes. In another embodiment, the metal oxide is titania.

In another embodiment, this invention provides a method for restoration of the hydrophilicity of a hydrophilic polyolefin article of this invention, wherein said metal oxide is titania, said method comprising exposing said titania layer to ultra violet (UV) light for a sufficient period of time, preferably 8-20 minutes, more preferably about 10 minutes.

The technology described herein enables modifying the surface of hydrophobic polyolefins in a systematic, robust fashion. It enables the painting and gluing of polyolefin surfaces and their incorporation into multi-layer implements of any size or shape. In one embodiment, this invention provides hydrophilic articles and methods of use thereof for painting and gluing of polyolefin based surfaces and their incorporation into multi-layer implements of any size or shape.

In one embodiment, the metal oxide surface treatment of the polyolefin article of this invention, allows for the application of an overcoating which then makes the overall structure impermeable to gasses or liquids.

In one embodiment, this invention provides hydrophilic articles, which can be used for preparing gas impermeable surfaces by subsequent overcoating with suitable barrier materials, i.e. which prevent gas from escaping and/or prevent permeation of a gas or liquid into the polyolefin object. Exemplary implementations include: car parts, gas impermeable insulating cases/containers, pipes for transport of non-polar liquids, storage containers for hydrocarbons and other non-polar liquids, etc.

In one embodiment, this invention provides hydrophilic articles and methods of use thereof for any application where a hydrophilic polyolefin surface is necessary or desirable. Nonlimiting examples of polymeric objects, that may be treated by the methods of this invention (i.e., coated with a thin layer of metal oxide), include but are not limited to: very small objects such as particulates or polymer coated powders, grains and the like, such as those that might be used as chromatographic media. Conversely, the polymeric objects may be very large such as truck components, jet skis, and boat hulls. Additional exemplary objects that may be modified with respect to their adhesive, paintability, polarity or reactivity characteristics include but are not limited to: particulate beds for bacterial growth; motorcycle components such as fuel tanks, fenders, and the like; automotive components such as A-, B- and C-pillars, fascias and the like; truck and RV components such as cabs, fenders, fascias and the like; passenger train, bus and aircraft components such as overhead baggage compartments, wall, ceiling and floor components and the like; farm equipment components such as roofs, tailgates, cabs and the like: watercraft components such as hulls, decks, roofs and the like: lawn and garden products such as furniture, fencing, blow molded sheds and the like, children's toys such as motorized vehicles, bikes, small scale automotive replicas and the like; tote boxes and containers such as tool boxes, cell phone housings, tool boxes and the like; building components such as window trim, siding, doors, garage doors, shingles, siding and the like; military components such as external panels on vehicles and helicopters, gun magazines and the like; home interior products such as cabinets, bathroom appliances, appliances such as cloths washing machines, dishwasher fronts and the like: out-of-doors products such as camper and cooler components and the like; sign and display components such as billboards, road signs and the like; micro-electronic components such as boards and medical device components and implants such as the inner surfaces of extracorporeal surfaces, catheters, stents, joint replacement components and drug delivery devices, and preparation of macroscopically enhanced surfaces such as visual, audio, or reactivity enhancement. Preferably, such hydrophilic polyolefins can be used as paintable road signs and insulating cases/containers. Other suitable uses include: insulting coating for electrical wiring, air filtration, air cleaning, water filtration, water cleaning, water purification, medical equipment, separation equipment, semiconductor manufacture, battery cell separator (particularly for batteries having aqueous based electrolytes), ultrafiltration equipment and the like.

The invention will now be illustrated by the following non-limiting examples. The following examples serve only to further illustrate aspects of the present invention and should not be construed as limiting the present invention.

### EXAMPLES

### Example 1

### Preparation of a Hydrophilic Polyolefin Articles

### a) Titanium Dioxide Coated Polyethylene by Liquid Phase Deposition (LPD)

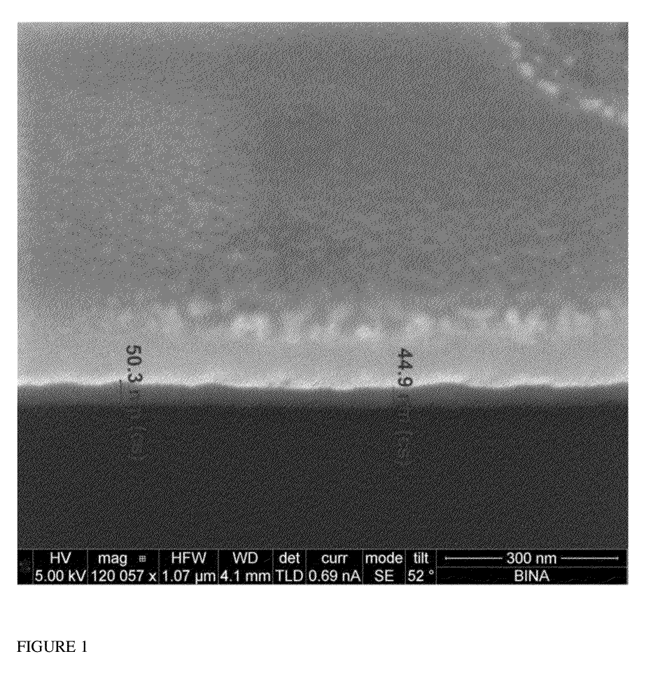

Polyethylene pieces were cleaned with ethanol and water, and dried with a stream of nitrogen. The contact angle of a water drop on this surface was ˜100°. The samples were treated in a plasma chamber (PDC-002, Harrick Plasma, USA) for 15 minutes at maximum intensity, with air flow of 140 SCCM). Immediately after the plasma treatment, the pieces were immersed for 6 hours into a room temperature, aqueous solution, containing (NH₄)₂TiF₆ (0.1 M) and H₃BO₃ (0.3 M). This process deposited a 50 nm thick, uniform, TiO₂ layer on the polyethylene surface (FIG. 1).

After the deposition, the samples were washed with water and methanol, and dried in a humidity/temperature controlled chamber using a program that combined temperatures between 25 and 70° C. and relative humidity of 20-70% over a period of about two days. This drying method minimizes/eliminates the cracking of the TiO₂ layer. The contact angle of the titania coated surface was ˜30°.

It was found that when drying is not done in a controlled fashion—i.e., without controlled humidity and for longer period than 1 hour, a cracked film might be obtained; however, the cracked film is still highly adherent and still works well for many/most applications.

### b) Tin Dioxide Films on Polyethylene Using Liquid Phase Deposition (LPD):

Polyethylene samples were cleaned with ethanol and water, and dried with a stream of nitrogen. The PE samples were treated in a plasma chamber (PDC-002, Harrick Plasma, USA) for 15 minutes at maximum intensity, with air flow of 140 SCCM). Immediately after the plasma treatment, the PE samples were immersed for 4 hrs. in 30° C., aqueous solution, containing SnF₂ (0.03 M), HF (0.12M), H₂O₂ (0.06M), and H₃BO₃ (0.45 M). This process deposited a uniform 50 nm SnO₂ layer on the polyethylene surface. The tin oxide film was washed with methanol and dried using a programmable humidity chamber wherein over a period of 53 h the relative humidity of the chamber was reduced from 70% to 20% while the temperature was maintained at 70° C.

### c) Titanium Dioxide Films on Polyethylene Using Atomic Layer Deposition (ALD):

Polyethylene samples were cleaned with ethanol and water, and dried with a stream of nitrogen. The PE samples were placed in an ALD chamber (Fiji F200, Cambridge Nanotech, USA) whose temperature was maintained between 80° C. and 100° C., with a constant argon flow of 240 SCCM. Oxygen flow was set to 30 SCCM, and the plasma generator was activated at 300 W for 2 minutes. After the plasma treatment the oxygen flow was stopped, and the PE samples were coated using repeated cycles of the following 4 steps:
(i) A pulse of Ti(N(CH₃)₂)₄, kept at 75° C., for 0.5 seconds.
(ii) 20 seconds of argon purge.
(iii) Oxygen plasma, 30 SCCM, 300 W, 20 seconds.
(iv) 10 seconds of argon purge.

After 200 cycles, this process deposited a uniform 15 nm TiO₂ layer on the PE samples.

### d) Aluminum Oxide Films on Polyethylene Using Atomic Layer Deposition (ALD):

Polyethylene samples were cleaned with ethanol and water, and dried with a stream of nitrogen. The samples were placed in an ALD chamber (Fiji F200, Cambridge Nanotech, USA) whose temperature was maintained between 80° C. and 100° C., with a constant argon flow of 240 SCCM. Oxygen flow was set to 30 SCCM, and the plasma generator was activated at 300 W for 2 minutes. After the plasma treatment the oxygen flow was stopped, and the pieces were coated using repeated cycles of the following 4 steps:
(v) A pulse of Al(CH₃)₃, not heated, for 0.06 seconds.
(vi) 20 seconds of argon purge.
(vii) Oxygen plasma, 30 SCCM, 300 W, 20 seconds.
(viii) 10 seconds of argon purge.

After 200 cycles, this process deposited a uniform 20 nm thick Al₂O₃ layer on the PE samples.

Extension to other oxide-substrate combinations is straightforward.

### Example 2

### Restoration of Hydrophilicity of a Hydrophilic Polyolefin Article

The hydrophilicity of the surface obtained in Example 1, remained unchanged over a period of a few days under ambient conditions, but it slowly became less hydrophilic after several weeks (with the observed contact angle approaching 70°). Assuming that this developing hydrophobicity was due to accumulated oils and random contaminants, we found that a 10 minute exposure to UV light completely restored the hydrophilicity of the surface.

### Example 3

### Stability and Robustness Properties of a Hydrophilic Polyolefin Article

The stability and robustness of the titania overlayer was challenged by subjecting the sample of Example 1(a) to a 900 bend, to direct impact with a chisel and to a high pressure water spray. Electron microscopy revealed some cracking in the titania but it remained completely adherent. When the sample was challenged by abrasion with sandpaper, the titania was removed along with a substantial erosion of the underlying polymer.

What is claimed is:

1. A hydrophilic polyolefin article comprising a polyolefin substrate, which comprises at least one polyolefin, coated with a thin film layer of a metal oxide.

2. The hydrophilic polyolefin article of claim 1, wherein said at least one polyolefin is polyethylene, polypropylene, polybutylene, polymethylpentene, a copolymer thereof, or any combination thereof or wherein said metal oxide is titania, alumina, zirconia, zinc oxide, or tin oxide.

3. The hydrophilic polyolefin article of claim 2, wherein said polyethylene is high density polyethylene (HDPE), low density polyethylene (LDPE), very low density polyethylene (VLDPE), linear low density polyethylene (LLDPE), medium density polyethylene (MDPE), ultra-high molecular polyethylene (UHMPE), crosslinked polyethylene (XLPE), high-pressure polyethylene (HPPE), or any combination thereof or wherein said polypropylene is isotactic polypropylene, syndiotactic polypropylene, metallocene catalyzed polypropylene, impact-modified polypropylene, biaxially oriented polypropylene (BOPP) or any combination thereof.

4. The hydrophilic polyolefin article of claim 1, wherein said polyolefin is a random or block copolymer based on ethylene and propylene.

5. The hydrophilic polyolefin article of claim 4, wherein said random or block copolymer based on ethylene and propylene is poly[ethylene-co-propylene](EPM).

6. The hydrophilic polyolefin article of claim 1, wherein said polyolefin substrate is coated with a uniform metal oxide film layer having a thickness of about 5 nm to about 30 μm or having a thickness of about 50 nm or said polyolefin is polyethylene, said metal oxide is titania, and said polyethylene is coated with a uniform 50 nm thick layer of titania or said polyolefin is polyethylene, said metal oxide is titania, and said polyethylene is coated with a uniform 50 nm thick layer of titania.

7. The hydrophilic polyolefin article of claim 1, wherein said article is in the form of granules, chips, pellets, films, sheets, fibers, tubes, or pipes.

8. A method for producing a hydrophilic polyolefin article comprising a polyolefin substrate, said method comprises:
(i) oxidizing one or more surfaces of the polyolefin substrate;
(ii) coating said one or more surfaces of the polyolefin substrate with a thin film layer of metal oxide.

9. The method of claim 8, further comprising a step of drying said metal oxide coated polyolefin substrate obtained in step (ii) under conditions that minimize cracking of said metal oxide layer.

10. The method of claim 8, wherein said oxidizing step (i) is performed by plasma, flame, ozone, ultra violet ozone cleaning systems (UVOCS), or etching with an oxidative solution or said polyolefin is polyethylene and the oxidizing step (i) is performed by plasma for approximately 15 minutes at maximum intensity with air flow of 140 standard cubic centimeters per minute (sccm).

11. The method of claim 8, wherein said coating step (ii) is performed by liquid phase deposition, atomic layer deposition or vapor phase techniques optionally, step (ii) is performed immediately after step (i).

12. The method of claim 11, wherein said liquid phase deposition comprises immersing said one or more oxidized surfaces of the polyolefin substrate obtained in step (i) in an aqueous solution containing metal oxide forming reagent for a sufficient period of time, optionally, said metal oxide forming reagent is selected from: (NH₄)TiF₆/H₃BO₃ (for TiO₂ deposition), H₂SnF₆/H₃BO₃ (for SnO₂ deposition), or combination thereof.

13. The method of claim 11, wherein said coating by atomic layer deposition comprises:
i. introducing said one or more oxidized surfaces of the polyolefin substrate and a metal oxide forming reagent into a closed chamber and allowing them to react for a sufficient period of time; and
ii. introducing an oxygen source into said chamber and allowing it to react for a sufficient period of time.

14. The method of claim 13, wherein said metal oxide forming reagent comprises: Al(CH₃)₃, Ti(NMe₂)₄, Zn(CH₂CH₃)₂, Sn(NMe₂)₄, Zr(NMe₂)₄ or any combination thereof or said oxygen source is plasma, ozone, O₂, H₂O or any combination thereof.

15. The method of claim 8, wherein said one or more oxidized surfaces of the polyolefin substrate obtained in step (i) are coated with a uniform layer of said metal oxide having a thickness of about 5 nm to about 30 μm or said thickness is about 50 nm or optionally one or more coated surfaces of the polyolefin obtained in step (ii) are further washed with water.

16. The method of claim 8, wherein said coating step (ii) is performed by liquid phase deposition and the obtained one or more coated surfaces of the polyolefin are further washed with C₁-C₄ alkanol, optionally said alkanol is methanol.

17. The method of claim 9, wherein said drying step is performed at a temperature in the range of 25 to 70° C. and at a relative humidity in the range of 20-70%.

18. A method of producing a hydrophilic polyethylene coated with a uniform layer of metal oxide having a thickness of about 50 nm, said method comprising:
(i) providing a polyethylene substrate;
(ii) oxidizing one or more surfaces of the polyethylene substrate by plasma;
(iii) immersing the one or more oxidized surfaces of the polyethylene substrate into an aqueous solution containing metal oxide forming reagent for a sufficient period of time at room temperature, to thereby coat said one or more oxidized surfaces with a uniform 50 nm thick layer of metal oxide; and
(iv) drying the metal oxide-coated polyethylene substrate obtained in step (iii) at a temperature in the range of 25 to 70° C. and at a relative humidity in the range of 20-70%.

19. The method according to claim 18, wherein said metal oxide is titania or tin oxide or said metal oxide forming reagent is (NH₄)TiF₆/H₃BO₃ or H₂SnF₆/H₃BO₃.

20. A method for restoration of the hydrophilicity of a hydrophilic polyolefin article according to claim 1, said method comprising exposing said metal oxide layer to ultra violet (UV) light for a sufficient period of time.
